(19) United States
(12) Patent Application Publication
(10) Pub. No.: US 2011/0063801 A1
(43) Pub. Date: Mar. 17, 2011

(54) ELECTRONIC DEVICE WITH A HEAT INSULATING STRUCTURE

(76) Inventors: Li-Tang Lin, Taipei City (TW); Ming-Cheng Hsieh, Yunlin County (TW)

(21) Appl. No.: 12/559,474

(22) Filed: Sep. 14, 2009

(51) Int. Cl. H05K 7/20

(52) U.S. Cl. 361/705; 361/720

(57) ABSTRACT

An electronic device includes a circuit board and a heat insulating structure. The heat insulating structure includes a heat source, an enclosure for covering the heat source, and a heat insulating plate disposed on a side of the enclosure facing to the heat source for preventing heat generated by the heat source from directly transmitting toward the enclosure, and a space being formed between the heat insulating plate and the enclosure. The heat insulating structure further includes a thermal conductive layer disposed on a side of the heat insulating plate facing to the heat source. The heat insulating structure further includes the thermal conductive layer disposed on a side of the heat insulating plate facing to the enclosure. Therefore, the heat insulating plate can be for altering heat current generated by the heat source so as to dissipate the heat current via holes on the enclosure uniformly.

### BACKGROUND OF THE INVENTION

1. Field of the Invention

The present invention relates to an electronic device, and more particularly, to an electronic device with a heat insulating structure capable of preventing heat from directly transmitting toward an enclosure.

2. Description of the Prior Art

With the advanced technology, a consumer electronic device includes several heat sources, such as a CPU (Central Processing Unit or SoC (System on Chip) or Power IC or a chip. Heat generated by the heat sources affects operational stability of the electronic device easily. Therefore, kinds of components are designed for dissipating the heat generated by the heat sources, such as a heat sink or a fan. Most enclosures of the electronic device can be made of plastic material. The plastic enclosure has low heat dissipating efficiency so that the heat generated by the heat sources and transmitting toward the enclosure directly warms the enclosure up violently. If temperature of the enclosure exceeds tolerance that a user's skin can bear, the user is hard to hold the electronic device, even being hurt by the heat. Thus, solution of the enclosure with high temperature is an important issue in the mechanical design industry.

### SUMMARY OF THE INVENTION

The present invention provides an electronic device with a heat insulating structure for solving above drawbacks.

According to the claimed invention, an electronic device includes a circuit board, and a heat insulating structure. The heat insulating structure includes a heat source disposed on the circuit board, an enclosure for covering the circuit board and the heat source, and a heat insulating plate disposed or glued on a side of the enclosure facing to the heat source for preventing heat generated by the heat source from directly transmitting toward the enclosure, and a space being formed between the heat insulating plate and the enclosure.

According to the claimed invention, the heat insulating structure further includes a thermal conductive layer disposed on a side of the heat insulating plate.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is an exploded diagram of an electronic device according to a first embodiment of the present invention.

FIG. 2 is a bottom view of an enclosure and a heat insulating plate according to the first embodiment of the present invention.

FIG. 3 is a lateral view of the enclosure and the heat insulating plate according to the first embodiment of the present invention.

FIG. 4 is a diagram of the electronic device according to a second embodiment of the present invention.

FIG. 5 is a diagram of the electronic device according to a third embodiment of the present invention.

FIG. 6 is a diagram of the electronic device according to a fourth embodiment of the present invention.

### DETAILED DESCRIPTION

In the following detailed description of the preferred embodiments, reference is made to the accompanying drawings which form a part hereof, and in which is shown by way of illustration specific embodiments in which the invention may be practiced. The components of the present invention can be positioned in a number of different orientations. As such, the directional terminology is used for purposes of illustration and is in no way limiting. It is to be understood that other embodiments may be utilized and structural changes may be made without departing from the scope of the present invention. Also, it is to be understood that the phraseology and terminology used herein is for the purpose of description and should not be regarded as limiting. The use of “including,” “comprising,” or “having” and variations thereof herein is meant to encompass the items listed thereafter and equivalents thereof as well as additional items. The terms “facing,” “faces” and variations thereof herein are used broadly and encompass direct and indirect facing, and “adjacent to” and variations thereof herein are used broadly and encompass directly and indirectly “adjacent to”. Therefore, the description of “A” component facing “B” component herein may contain the situations that “A” component facing “B” component directly or one or more additional components is between “A” component and “B” component. Also, the description of “A” component “adjacent to” “B” component herein may contain the situations that “A” component is directly “adjacent to” “B” component or one or more additional components is between “A” component and “B” component. Accordingly, the drawings and descriptions will be regarded as illustrative in nature and not as restrictive.

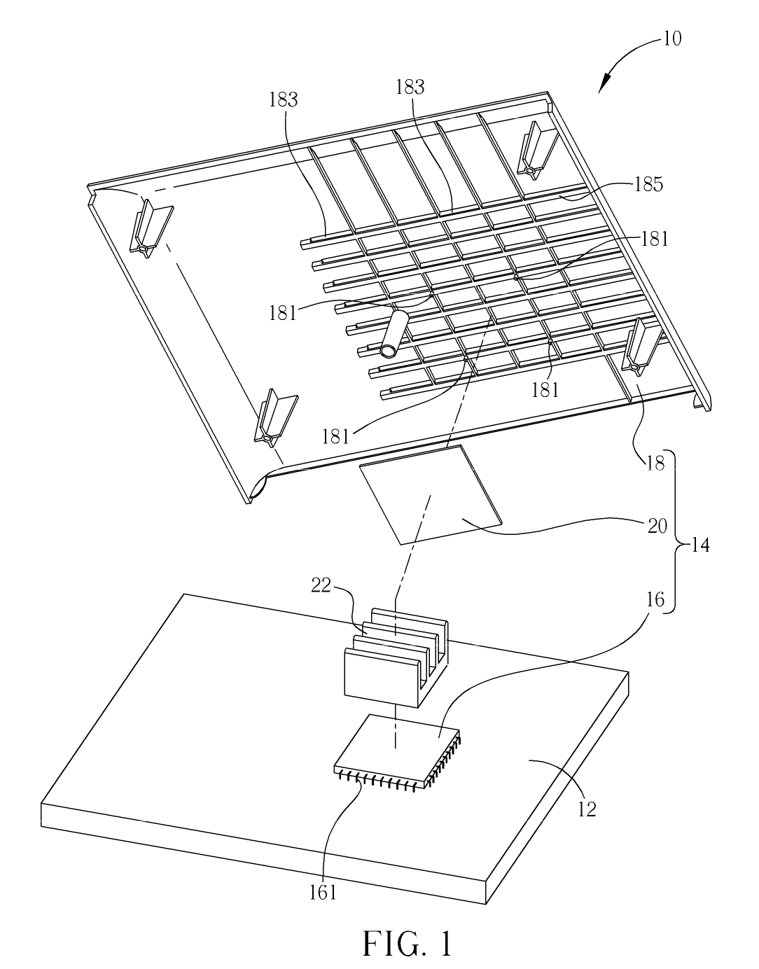

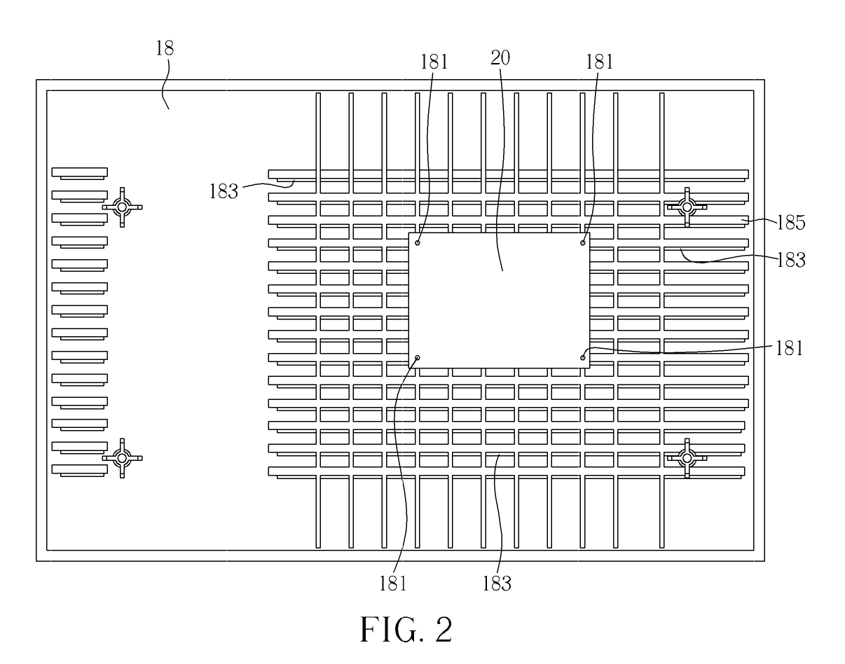

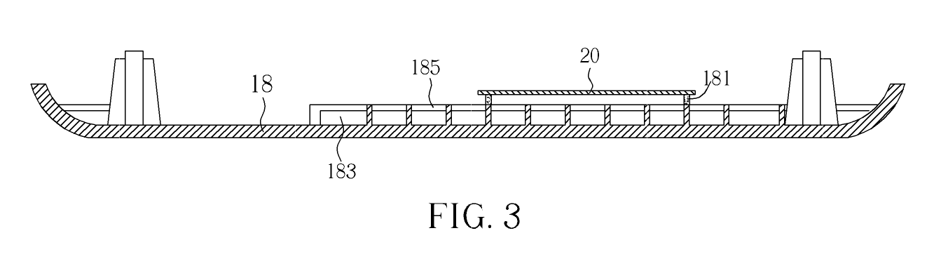

Please refer to FIG. 1. FIG. 1 is an exploded diagram of an electronic device 10 according to a first embodiment of the present invention. The electronic device 10 includes a circuit board 12 and a heat insulating structure 14. The heat insulating structure 14 includes a heat source 16 disposed on the circuit board 12, an enclosure 18 for covering the circuit board 12 and the heat source 16, and a heat insulating plate 20 disposed on a side of the enclosure 18 facing to the heat source 16 for preventing heat generated by the heat source 16 from directly transmitting toward the enclosure 18. Please refer to FIG. 1 to FIG. 3. FIG. 2 is a bottom view of the enclosure 18 and the heat insulating plate 20 according to the first embodiment of the present invention. FIG. 3 is a lateral view of the enclosure 18 and the heat insulating plate 20 according to the first embodiment of the present invention. A space is formed between the heat insulating plate 20 and the enclosure 18. The heat insulating plate 20 can be disposed on the enclosure 18 in a heat melt manner. For example, the enclosure 18 can include at least one heat stake 181 so that the heat insulating plate 20 can be staked on the heat stake 181 by a heat melt manner. The heat insulating plate 20 also can be glued on the enclosure 18. The heat insulating plate 20 can further be disposed on the enclosure 18 by the heat melt manner with wall structure, circular structure, or the combination of the wall structure, circular structure, and the heat stake 181. The heat insulating plate 20 can further be integrated with the enclosure 18 monolithically. In addition, at least one hole 183 is formed on the enclosure 18 for dissipating the heat generated by the heat source 16 effectively and at least one rib 185 can be formed on the enclosure 18 for strengthening loading bearing on the enclosure 18. The hole 183 can be formed adjacent to the rib 185, respectively. Assembly of the heat insulating plate 20 on the enclosure 18 is not limited to the above-mentioned embodiment and depends on design demand. The heat insulating structure 14 can further include a heat dissipating component 22 disposed on the heat source 16 for dissipating the heat generated by the heat source 16. For example, the heat dissipating component 22 can be a heat sink, a thermal pad, or any other material which can dissipate heat. In order to prevent the heat generated by the heat source 16 from directly transmitting toward the enclosure 18, dimensions of the heat insulating plate 20 is larger than or equal to dimensions of the heat source 16 or the heat dissipating component 22 in a preferred embodiment. Corresponding dimensions of the heat insulating plate 20, the heat source 18, and the heat dissipating component 22 are not limited to the above-mentioned method, and it depends on design demand. In addition, the heat insulating plate 20 can be made of plastic material, such as Mylar material, so as to insulate the heat effectively. The heat insulating plate 20 can further be the thermal pad. The heat insulating plate 20 is not limited to the above-mentioned material and depends on design demand.

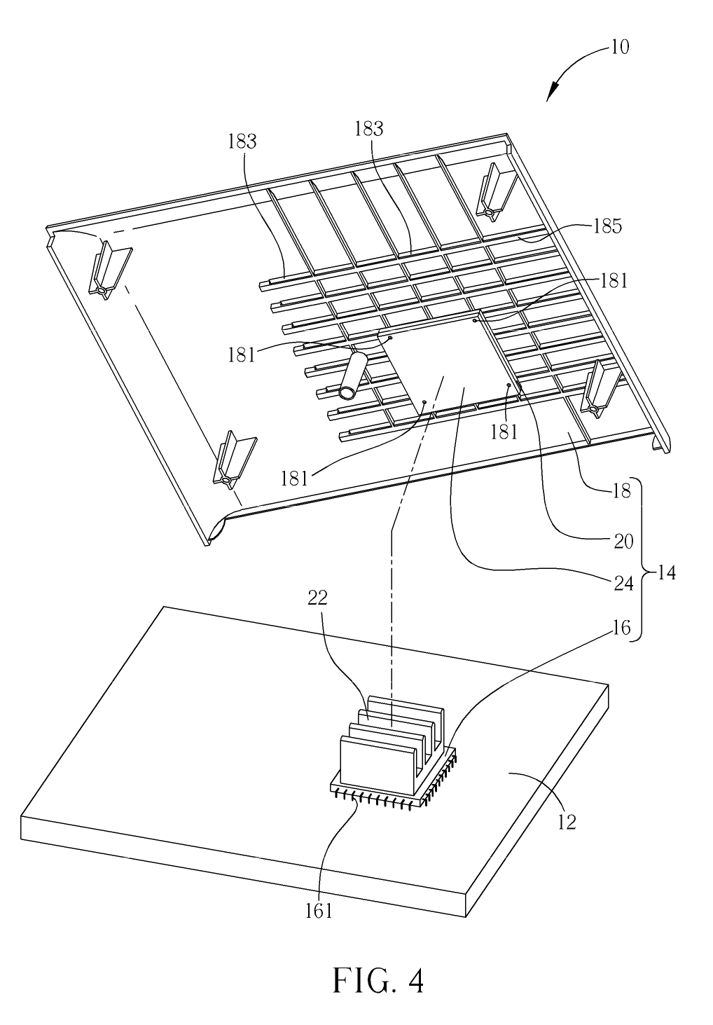

Please refer to FIG. 4. FIG. 4 is a diagram of the electronic device 10 according to a second embodiment of the present invention. In above embodiments, components have the same numerals as the above-mentioned embodiment have the same structures and functions and the detail description is omitted herein for simplicity. As shown in FIG. 4, the heat insulating structure 14 can further include a thermal conductive layer 24 disposed on a side of the heat insulating plate 20 facing to the heat source 16 for improving heat dissipating efficiency of the heat insulating plate 20. The thermal conductive layer 24 can be made of metal material or graphite material having preferred heat conductivity, such as copper, alumni and so on. Shape of the thermal conductive layer 24 is designed according to mechanical demand, such as a membrane or a mesh, and corresponding dimensions of the thermal conductive layer 24 and the heat insulating 20 are designed according to the actual demand. In addition, part of the enclosure 18 can be an upper housing of the electronic device 10.

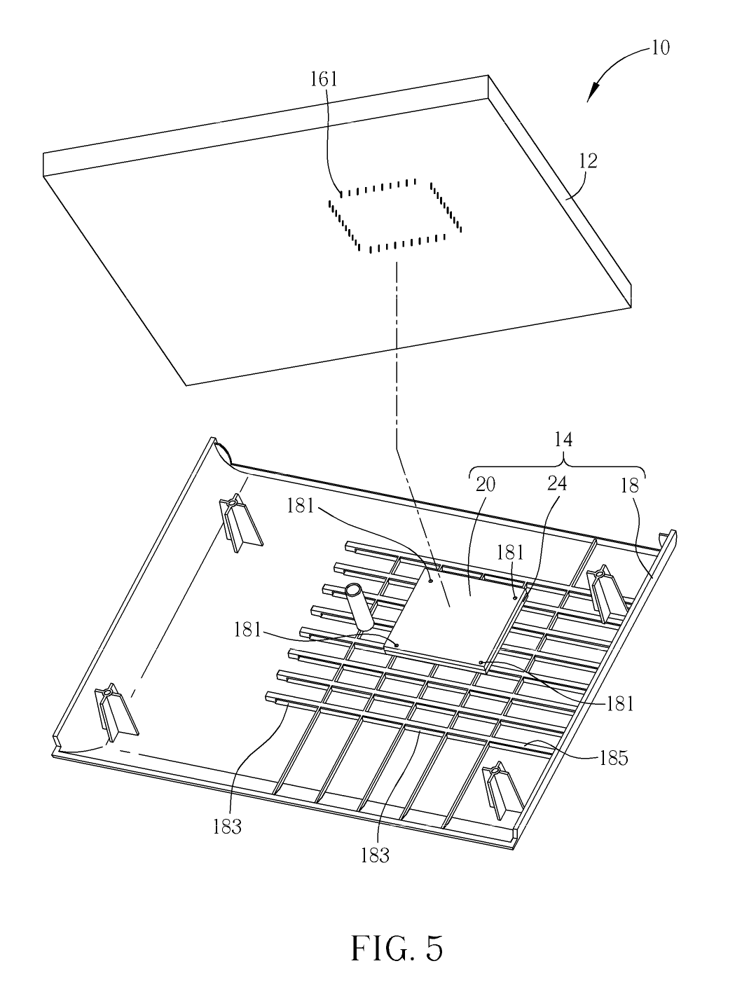

Please refer to FIG. 5. FIG. 5 is a diagram of the electronic device 10 according to a third embodiment of the present invention. The heat insulating structure 14 can further include the thermal conductive layer 24 disposed on a side of the heat insulating plate 20 facing to the enclosure 18 for improving the heat dissipating efficiency of the heat insulating plate 20. Because pins 161 of the heat source 16 (not be shown in FIG. 5) mounted on the circuit board 12 might pierce through a side of the circuit board 12 opposite to the other side of the circuit board 12 whereon the heat source 16 disposed, the heat insulating plate 20 can be further utilized for insulating electrical connection of the circuit board 12 and the thermal conductive layer 24. The thermal conductive layer 24 can be made of metal material having preferred heat conductivity, such as copper, alumni and so on. Shape of the thermal conductive layer 24 is designed according to mechanical demand, such as a membrane or a mesh, and the corresponding dimensions of the thermal conductive layer 24 and the heat insulating 20 are designed according to the actual demand. In addition, part of the enclosure 18 can be a lower housing of the electronic device 10.

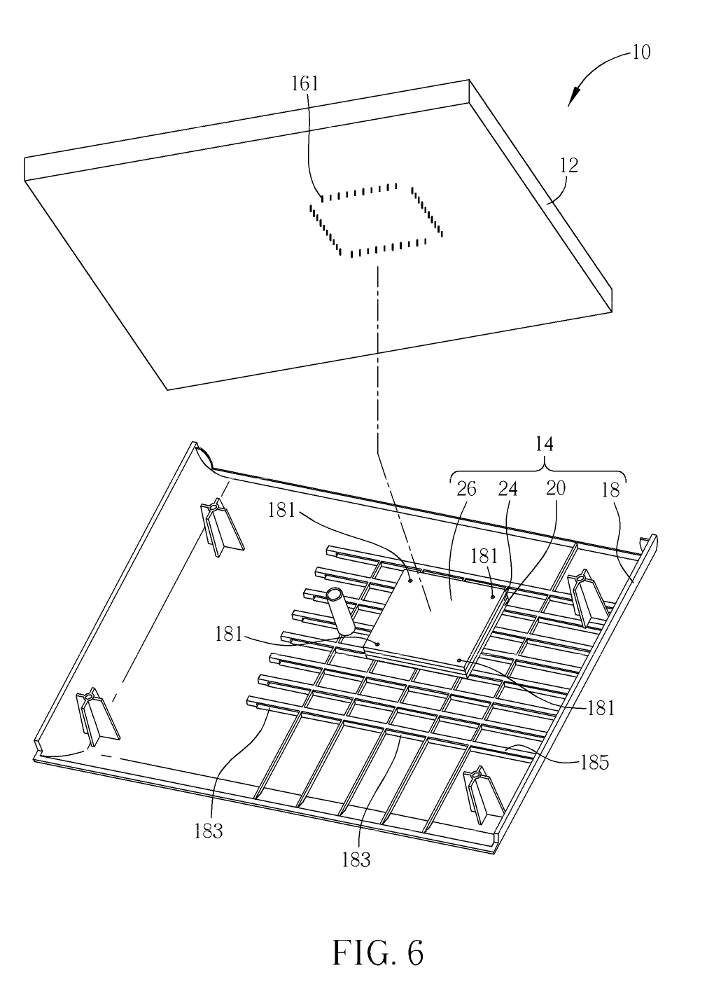

Please refer to FIG. 6. FIG. 6 is a diagram of the electronic device 10 according to a fourth embodiment of the present invention. The heat insulating structure 14 including the thermal conductive layer 24 disposed on the side of the heat insulating plate 20 facing to the circuit board 12 can further include an insulating layer 26 disposed between the thermal conductive layer 24 and the circuit board 12. The insulating layer 26 can insulate electrical connection of the circuit board 12 and the thermal conductive layer 24 so that the thermal conductive layer 24 can be disposed between the heat insulating plate 20 and the circuit board 12. In this embodiment, elements have the same numerals as the third embodiment have the same structures and functions, and detail description is omitted herein for simplicity.

In conclusion, design of the heat insulating plate 20 disposed between the enclosure 18 and the heat source 16 can prevent the heat generated by the heat source 16 from transmitting toward the enclosure 18 effectively. The heat insulating plate 20 can be disposed on the enclosure in the heat melt manner, such as being staked on the heat stake 181, so as to economize manufacturing cost and labor hours. In addition, because the heat generated by the heat source 16 can be transmitted by conduction, radiation, and convection, the space formed between the heat insulating plate 20 and the enclosure 18 can be for preventing heat dissipated from the heat insulating plate 20 from conducting toward the enclosure 18 directly. The heat insulating plate 20 also can be directly connected to the enclosure 18 without intervening space. The heat insulating plate 20 can be utilized for altering upward heat current generated by the heat source 16 to dissipate laterally so as to dissipate the heat current via neighboring holes 183 on the enclosure 18 uniformly. The heat insulating plate 20 can be made of heat insulating material having low heat dissipating efficiency. The heat insulating plate 20 can further be made of thermal conductive material, such as graphite material. The heat insulating structure 14 can further include the thermal conductive layer 24 disposed on the side of the heat insulating plate 20 facing to the heat source 16 for dissipating the heat transmitting toward the heat insulating plate 20 and the enclosure 18 when the heat insulating plate 20 is disposed on the upper housing of the electronic device 10 as shown in FIG. 4. The thermal conductive layer 24 is for dissipating the heat transmitting from the heat source 16 first, so as to decrease the heat transmitting toward the heat insulating plate 20 and the enclosure 18. For this reason, the heat generated by the heat source 16 is not transmitted toward the enclosure 18 directly by setting the heat insulating plate 20 and the thermal conductive layer 24 so as to cool down temperature of the enclosure 18.

Because an interval between the circuit board 12 and the lower housing of the electronic device 10 is small due to limitation of mechanical arrangement, the heat insulating structure 14 can further include the thermal conductive layer 24 disposed by the side of the heat insulating plate 20 facing to the enclosure 18 when the heat insulating plate 20 is disposed or glued on the lower housing of the electronic device 10 as shown in FIG. 5. For preventing the pins of the heat source 16 piercing through the side of the circuit board 12 from contacting with the thermal conductive layer 24, the thermal conductive layer 24 can be disposed by the side of the heat insulating plate 20 facing to the enclosure 18 so as to avoid a short circuit. The thermal conductive layer 24 is for dissipating the heat transmitting from the heat insulating plate 20, and disposition of the heat insulating plate 20 can be for insulating electrical connection of the circuit board 12 and the thermal conductive layer 24. The heat generated by the heat source 16 is not transmitted toward the enclosure 18 directly by setting the heat insulating plate 20 and the thermal conductive layer 24 so as to cool down the temperature of the enclosure 18.

Comparing to the prior art, the present invention provides the heat insulating structure with enhanced heat insulating efficiency. The heat insulating plate can insulate the heat generated by the heat source transmitting toward the enclosure so as to cool down the temperature of the enclosure, and the thermal conductive layer can further assist dissipation of the heat transmitting from the heat insulating plate effectively. Therefore, the present invention provides a new design for preventing the enclosure of the electronic device from heating and has advantages of low cost and convenient assembly.

Those skilled in the art will readily observe that numerous modifications and alterations of the device and method may be made while retaining the teachings of the invention.

What is claimed is:

1. An electronic device comprising:
a circuit board; and
a heat insulating structure comprising:
a heat source disposed on the circuit board;
an enclosure for covering the circuit board and the heat source; and
a heat insulating plate disposed on a side of the enclosure facing to the heat source for preventing heat generated by the heat source from directly transmitting toward the enclosure.

2. The electronic device of claim 1, wherein a space is formed between the heat insulating plate and the enclosure.

3. The electronic device of claim 1, wherein the heat insulating structure further comprises a heat dissipating component disposed on the heat source for dissipating the heat generated by the heat source.

4. The electronic device of claim 1, wherein the heat insulating structure further comprises a thermal conductive layer disposed on a side of the heat insulating plate facing to the heat source.

5. The electronic device of claim 4, wherein the thermal conductive layer is made of metal material or graphite material.

6. The electronic device of claim 4, wherein the heat insulating structure further comprises an insulating layer disposed between the thermal conductive layer and the circuit board for insulating electrical connection of the circuit board and the thermal conductive layer.

7. The electronic device of claim 1, wherein the heat insulating structure further comprises a thermal conductive layer disposed on a side of the heat insulating plate facing to the enclosure.

8. The electronic device of claim 7, wherein the thermal conductive layer is made of metal material or graphite material.

9. The electronic device of claim 7, wherein the heat insulating plate is for insulating electrical connection of the circuit board and the thermal conductive layer.

10. The electronic device of claim 1, wherein the heat insulating plate is disposed on the enclosure by a heat melt manner.

11. The electronic device of claim 1, wherein the heat insulating plate is integrated with the enclosure monolithically.

12. The electronic device of claim 1, wherein the heat insulating plate is glued on the enclosure.

13. The electronic device of claim 11, wherein the enclosure comprises at least one heat stake and the heat insulating plate is staked on the heat stake.

14. The electronic device of claim 1, wherein at least one hole is formed on the enclosure for dissipating the heat generated by the heat source.

15. The electronic device of claim 1, wherein the heat insulating plate is made of plastic material.

16. The electronic device of claim 15, wherein the heat insulating plate is made of Mylar.

17. The electronic device of claim 1, wherein the heat insulating plate is made of thermal conductive material.

18. The electronic device of claim 17, wherein the heat insulating plate is made of metal material or graphite material.

19. The electronic device of claim 1, wherein dimensions of the heat insulating plate are larger than or equal to dimensions of the heat source.

20. The electronic device of claim 1 being a set-top box (STB).
